(19) United States
(12) Patent Application Publication
(10) Pub. No.: US 2019/0146047 A1
(43) Pub. Date: May 16, 2019

(54) METHOD FOR IMPROVING SIGNAL-TO-NOISE RATIO IN MAGNETIC RESONANCE IMAGING

(71) Applicant: Weinberg Medical Physics, Inc., North Bethesda, MD (US)

(72) Inventor: Irving N. WEINBERG, North Bethesda, MD (US)

(21) Appl. No.: 16/185,418

(22) Filed: Nov. 9, 2018

Related U.S. Application Data
(60) Provisional application No. 62/584,469, filed on Nov. 10, 2017.

(51) Int. Cl. G01R 33/56

(52) U.S. Cl. CPC G01R 33/5607; G06T 11/005; G01R 33/5608

(57) ABSTRACT

An imaging apparatus and methodologies image a subject using Magnetic Resonance Imaging, wherein the imaging apparatus uses different time properties of signal and noise to discriminate against noise signals, and thereby improve overall Signal-to Noise Ratio.

### CROSS REFERENCE AND PRIORITY CLAIM

This patent application claims priority to U.S. Provisional Application Provisional Patent Application No. Patent Application Ser. No. 62/584,469, entitled “METHOD FOR IMPROVING SIGNAL-TO-NOISE RATIO IN MAGNETIC RESONANCE IMAGING,” filed Nov. 10, 2017, the disclosure of which being incorporated herein by reference in its entirety.

### FIELD

Disclosed embodiments provide a method and apparatus for Magnetic Resonance Imaging (MRI) of living beings or examination of inanimate objects.

### BACKGROUND

In conventional MRI scanners, the maximization of Signal-to-Noise Ratio (SNR) in images is critical for achieving high accuracy when the images are used to diagnose disease. Conventional MRI systems attempt to maximize SNR by collecting images for long periods of time. This conventionally-accepted, long acquisition time effectively reduces noise by increasing count statistics. However, this conventional solution also leads to long MRI sessions, which adds to the labor cost of the MRI examination, and reduces the ability to use real-time MRI guidance for clinical procedures that require delivery of accurate images in a time period that enables reliance on objects being positioned in the place they are shown in those images, which decreases over time.

### SUMMARY

Disclosed embodiments provide a new imaging apparatus and methodologies to image a subject using an MRI, wherein the imaging apparatus uses different time properties of signal and noise to discriminate against noise signals, and thereby improve overall SNR.

### BRIEF DESCRIPTION OF THE FIGURES

The detailed description particularly refers to the accompanying figures in which:

FIG. 1 is an illustration of typical MRI signals obtained in time from a single location in k-space, along with a trend line.

FIG. 2 illustrates the steps that may be obtained to implement the method.

### DETAILED DESCRIPTION

It is known that MRI signals emanating from an object of interest in the field-of-view of the MRI will have an overall decay with a time-constant that is characteristic of the materials in the object. This property is described by the well-known Bloch equation.

For example, if the object is water, the decay constant may be on the order of several seconds, and the shape of the overall decay curve is exponential in time. Sometimes additional factors (e.g. inhomogeneous magnetic fields) can lengthen or shorten the decay time further, but in general the shape of the MRI signal decay curve from a particular location still decays exponentially in time. Noise can be from local radio stations, or radiation from the body, or from many other sources. In general, noise need not be exponential in time.

Disclosed embodiments, therefore, use the different time properties of signal and noise to discriminate against noise signals, and thereby improve overall SNR.

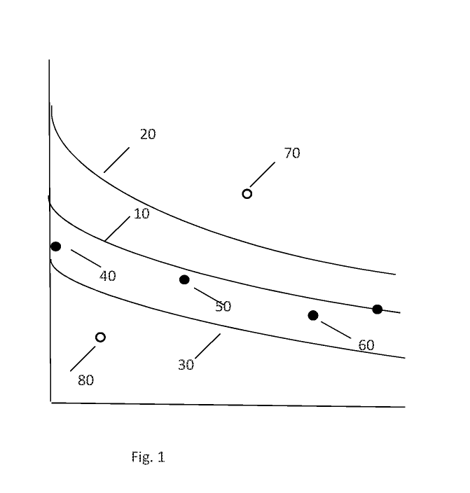

As an illustration of the presently disclosed embodiments, FIG. 1 shows a set of MRI measurements of radio-frequency (RF) signal magnitude in time obtained from an object in the field-of-view of the MRI. Two representative measurement data points are labeled as 40-60 (filled circles) and 70-80 (unfilled circles), respectively.

As shown in FIG. 1, the horizontal axis is time, and the vertical axis is the absolute magnitude of signal. The measurements were obtained in a specific location in k-space from an object that was in the field-of-view of the MRI. By k-space, it is understood that the x-value-axis represents the evolution in time of the RF signal after an RF excitation. The y-value-axis represents the same evolution in time after a given number of phase encoding steps. Thus, the set of x-values in k-space can be considered as the frequency direction, and the set of y-values in k-space can be considered as the phase direction, in the sense that is commonly understood in MRI as the k-space representation. In a conventional MRI system, many, if not all, the values 40 and 50 would be used to reconstruct an image using Fourier transformation.

Also shown in FIG. 1, is a trend line 10 that is an exponential fit to the measurements at the specific location in k-space. In drawing the trend line, a fitting routine was used whose initial guess at a decay constant may have been determined from an exponential curve fit to the overall magnitude of the entire k-space array. Upper and lower bounds 20 and 30 respectively are curves that are some multiple of the trend line 10.

Those bound limits may be selected by the user or may be set automatically in order to discriminate against noise. The justification for this discrimination is that points outside of the bounds do not obey an exponential curve, and are, therefore, likely to represent noise.

As shown in FIG. 1, point 70 is above the upper bound, point 80 is below the lower bound while points 40-60 are between the upper and lower bounds.

In accordance with disclosed embodiments, points 70 and 80 (and other points outside of the curve bounds) are removed from the next step of the reconstruction. Accordingly, an image is then reconstructed using only the remaining measurement points.

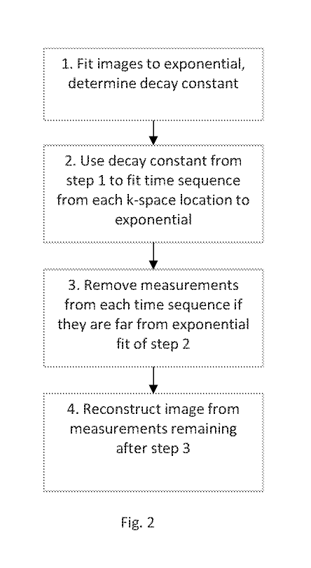

FIG. 2 illustrates an example of the above-identified process including various operations to provide the reconstructed image. More specifically, the operations begin at 200 and control proceeds to 205, at which a first approximation of a decay constant for the decay of MRI signals from the object of interest is collected from the entire image data, or from sections of the image data provided by the MRI system. Control then proceeds to 210, at which that decay constant is used to help fit a decay curve to measurements from a single location in k-space. Control then proceeds to 215, at which measurements that do not fit the decay curve are rejected as noise. Control then proceeds to 220, at which only the remaining measurements are used to reconstruct the image of the entire object. Control then proceeds to 225, at which the reconstructed image data is output to either a display, a memory storage or other equipment for use in subsequent processing.

It is understood that different constituents at locations in the object of interest may have different decay times. As a result, it may be difficult to fit the signal magnitudes from the entire image to a single decay constant. One solution is to fit the time-dependent values to a curve with multiple decay constants. Another solution is to evaluate sections of the images (for example, voxels that are a millimeter in each direction), those sections being so small that they are constituted primarily by one material. In that way, the decay constant of the one material will dominate the decay curve and enable fitting.

It is understood that the term “trend line” implies a fitting routine, which may be computationally slow to implement, but that the same requirement for fitting to a curve may be implemented rapidly (for example, with a least-squares algorithm).

Although the disclosed embodiments have been illustrated with a single representative k-space formulation of a pulse sequence, it is understood that the same inventive concept may be applied to different types of pulse sequences. Most broadly, the disclosed innovation applies a priori knowledge of the type of MRI measurements collected in order to discriminate against noise (which does not follow such characteristic behavior).

In the presented example, an exponential decay was used to model the MRI measurements. However, other MRI data sets may have different behavior in time that can be used to apply bounds for inclusion of some measurement points as signal and exclusion of some measurement points as noise.

If the values in the time sequence do not correspond to a decaying exponential or exponentials, those values may be rejected as being noise (and not from the actual object being examined). It is understood that chemicals of different types (and with different decay times) may be resident in a single pixel. However, the invention presumes that for small enough pixels, a majority of a few (for example, less than five) chemical species may be present so that the decay curve will be dominated by the decay characteristics of those species.

It is understood that the term “signal-to-noise ratio” is one of several possible descriptors of image quality. For the purposes of this disclosure, image improvement could be measured with other descriptors, for example “contrast-to-noise ratio”).

For the purposes of this specification, the term “subject” is understood to be a human or other animal with or without illness.

It is understood that an apparatus for analyzing the MRI image data described above in accordance with the disclosed methodology may be used in conjunction with other components, for example a computer and/or a power supply and/or coils for generating magnetic and/or electromagnetic fields, in order to attain a desired result of a meaningful image. It is understood that the image may use principles of proton magnetic resonance imaging, or magnetic resonance imaging of other particles (for example, electrons or sodium atoms) or other imaging principles (for example magnetic particle imaging, or impedance imaging).

It should also be understood that the apparatus may be used to deliver therapy by manipulating magnetizable materials with the magnetic field produced by an MRI. It should be understood that such manipulation may be performed at one time, and that imaging may be performed at another time, in order to guide said manipulation.

For the purpose of the disclosed embodiments, the term “imaging” includes imaging technology that utilize components to form an image using magnetic resonance or magnetic particle imaging. It should be understood that such components include coils or magnets (or electro-permanent magnets) that polarize protons or other nuclei or electrons in one or more structures to be imaged, wherein gradient and/or radiofrequency coils form an image. Thus, although not shown in detail herein, it should be understood that the disclosed embodiments may be used in conjunction with a support structure that may hold an imaging system and may contain other components needed to operate or move the imaging system, for example, wheels and/or batteries.

Moreover, it should be understood that an associated display system is not shown but should be understood to be present in order to view images produced by the imaging system.

Further, it should be understood that disclosed embodiments may image one or more structures for segments of the one or more structure at a time, since it may be difficult in a single-sided MRI to obtain very good uniformity over the entirety of a structure to be imaged. It should be understood that the spatial resolution of certain portions of one or more structures to be imaged, e.g., breast tissues, may be different than in other portions, depending on the gradient applied at the time of image acquisition, which may be useful in order to better characterize certain regions of tissues.

It should be understood that the operations explained herein may be implemented in conjunction with, or under the control of, one or more general purpose computers running software algorithms to provide the presently disclosed functionality and turning those computers into specific purpose computers.

Moreover, those skilled in the art will recognize, upon consideration of the above teachings, that the above exemplary embodiments may be based upon use of one or more programmed processors programmed with a suitable computer program. However, the disclosed embodiments could be implemented using hardware component equivalents such as special purpose hardware and/or dedicated processors. Similarly, general purpose computers, microprocessor based computers, micro-controllers, optical computers, analog computers, dedicated processors, application specific circuits and/or dedicated hard wired logic may be used to construct alternative equivalent embodiments.

Moreover, it should be understood that control and cooperation of the above-described components may be provided using software instructions that may be stored in a tangible, non-transitory storage device such as a non-transitory computer readable storage device storing instructions which, when executed on one or more programmed processors, carry out the above-described method operations and resulting functionality. In this case, the term non-transitory is intended to preclude transmitted signals and propagating waves, but not storage devices that are erasable or dependent upon power sources to retain information.

Those skilled in the art will appreciate, upon consideration of the above teachings, that the program operations and processes and associated data used to implement certain of the embodiments described above can be implemented using disc storage as well as other forms of storage devices including, but not limited to non-transitory storage media (where non-transitory is intended only to preclude propagating signals and not signals which are transitory in that they are erased by removal of power or explicit acts of erasure) such as for example Read Only Memory (ROM) devices, Random Access Memory (RAM) devices, network memory devices, optical storage elements, magnetic storage elements, magneto-optical storage elements, flash memory, core memory and/or other equivalent volatile and non-volatile storage technologies without departing from certain embodiments. Such alternative storage devices should be considered equivalents.

While certain illustrative embodiments have been described, it is evident that many alternatives, modifications, permutations and variations will become apparent to those skilled in the art in light of the foregoing description. Accordingly, the various embodiments, as set forth above, are intended to be illustrative, not limiting. Various changes may be made without departing from the spirit and scope of the invention.

What is claimed:

1. An apparatus for magnetic resonance imaging of at least one object of interest, the apparatus comprising:
a magnetic resonance imaging system for performing an imaging process to image the at least one object of interest, the magnetic resonance imaging system including at least one power source coupled to a processor that controls operation of the magnetic resonance imaging system to generate at least one magnetic field gradient and generate radio waves for application to the at least one object of interest to elicit an electromagnetic response from atoms and molecules included in the at least one object of interest,
wherein the magnetic resonance imaging system includes at least one detector that detects the electromagnetic response and the processor generates the image of the at least one object of interest based on the detected electromagnetic response, wherein the processor applies limits that exclude noise on the basis of time-dependent behavior that is uncharacteristic of the magnetic resonance signal.

2. The apparatus of claim 1, wherein the time-dependent behavior that is uncharacteristic of the magnetic resonance signal is an exponential decay of one chemical species.

3. The apparatus of claim 1, wherein a voxel size is selected that is small enough so that the decay characteristic of one chemical species is dominant.

4. The apparatus of claim 1, wherein the time-dependent behavior that is uncharacteristic of the magnetic resonance signal is an exponential decay of less than five chemical species.

5. The apparatus of claim 1, wherein the imaging apparatus uses different time properties of signal and noise to discriminate against noise signals.

6. The apparatus of claim 1, wherein the processor further performs reconstruction to generate an image of the at least one object of interest and wherein the exclusion of noise is performed prior to the processor performing reconstruction.

7. A method for magnetic resonance imaging of at least one object of interest, the method comprising:
performing imaging processing using a magnetic resonance imaging system to image the at least one object of interest, wherein the magnetic resonance imaging system includes at least one power source coupled to a processor that controls operation of the magnetic resonance imaging system to generate at least one magnetic field gradient and generate radio waves for application to the at least one object of interest to elicit an electromagnetic response from atoms and molecules included in the at least one object of interest, wherein the magnetic resonance imaging system includes at least one detector that detects the electromagnetic response,
wherein the processor generates the image of the at least one object of interest based on the detected electromagnetic response, wherein the processor applies limits that exclude noise on the basis of time-dependent behavior that is uncharacteristic of the magnetic resonance signal.

8. The method of claim 7, wherein the time-dependent behavior that is uncharacteristic of the magnetic resonance signal is an exponential decay of one chemical species.

9. The method of claim 7, wherein a voxel size is selected that is small enough so that the decay characteristic of one chemical species is dominant.

10. The method of claim 7, wherein the time-dependent behavior that is uncharacteristic of the magnetic resonance signal is an exponential decay of less than five chemical species.

11. The method of claim 7, wherein the imaging apparatus uses different time properties of signal and noise to discriminate against noise signals.

12. The method of claim 7, wherein the processor further performs reconstruction to generate an image of the at least one object of interest and wherein the exclusion of noise is performed prior to the processor performing reconstruction.
